(19) United States
(12) Patent Application Publication
(10) Pub. No.: US 2022/0383475 A1
(43) Pub. Date: Dec. 1, 2022

(54) METHOD FOR IDENTIFYING POTENTIAL LANDSLIDE HAZARD OF RESERVOIR BANK BASED ON ROCK MASS DEGRADATION FEATURE

(71) Applicant: Wuhan Center, China Geological Survey (Central South China Innovation Center for Geosciences), Wuhan (CN)

(72) Inventors: Zhenwei Dai, Wuhan (CN); Yueping Yin, Wuhan (CN); Bolin Huang, Wuhan (CN); Xiaolin Fu, Wuhan (CN); Chenyang Zhang, Wuhan (CN); Yanjun Zhang, Wuhan (CN); Runqing Ye, Wuhan (CN)

(73) Assignee: Wuhan Center, China Geological Survey (Central South China Innovation Center for Geosciences), Wuhan (CN)

(21) Appl. No.: 17/584,439

(22) Filed: Jan. 26, 2022

(30) Foreign Application Priority Data
May 25, 2021 (CN) 202110569567.0

(51) Int. Cl. G06T 7/00; G01V 8/00; G06V 20/17; G06T 17/05; G06T 15/04; G06F 30/20

(52) U.S. Cl. CPC G06T 7/0002; G01V 8/00; G06V 20/17; G06T 17/05; G06T 15/04; G06F 30/20; G06T 2207/30181; G06T 2207/10032

(57) ABSTRACT

A method for identifying a potential landslide hazard of a reservoir bank based on a rock mass degradation feature, includes: determining a remote sensing interpretation identification mark of a potential landslide hazard site induced by rock mass degradation of a hydro-fluctuation belt of a bank slope, and establishing a potential landslide hazard site catastrophe evolution identification model; obtaining an orthoimage of a degradation belt, performing preliminary remote sensing interpretation on the orthoimage, and delineating an area prone to landslide; obtaining an oblique real-scene three-dimensional model of the area prone to landslide by the orthoimage, generating digital elevation model (DEM) data according to the oblique real-scene three-dimensional model for remote sensing fine interpretation, and identifying and extracting the mark; and inputting the mark into the potential landslide hazard site catastrophe evolution identification model to identify a catastrophe evolution mode of the potential landslide hazard site of the degradation belt.

### CROSS-REFERENCE TO RELATED APPLICATIONS

This application claims priority to Chinese Patent Application No. 202110569567.0 with a filing date of May 25, 2021. The content of the aforementioned application, including any intervening amendments thereto, is incorporated herein by reference.

### TECHNICAL FIELD

The present disclosure relates to the technical field of geological disaster identification, and particularly relates to a method for identifying a potential landslide hazard of a reservoir bank based on a rock mass degradation feature.

### BACKGROUND ART

Many large hydropower stations under construction or normally operating in China are located in the alpine and gorge regions with steep mountains, and the terrain and geological conditions are very complex. In the operation process of the reservoir, periodic water storage and drainage cause long-term repeated and large fluctuation of the reservoir water level, for example, the reservoir water level of the Longtan hydropower station has a periodic fluctuation at 330 m-400 m (70 m fluctuation); the reservoir water level of the Xiluodu hydropower station has a periodic fluctuation at 540 m-600 m (60 m fluctuation); and the reservoir water level of the Three Gorges Reservoir has a periodic fluctuation at 145 m-175 m (30 m fluctuation). Influenced by the periodic change of the geological environment conditions (such as stress, strain, temperature, etc.) caused by the fluctuation of the water level, the rock mass, formed by the periodic fluctuation of the reservoir water level, of the hydro-fluctuation belt of the reservoir bank has the physical and mechanical properties of the rock mass changed, and the rock mass is degraded. Since 175 m experimental water storage of the Three Gorges Reservoir in 2008, the hidden geological disaster caused by rock mass degradation of the hydro-fluctuation belt of the reservoir bank has been increased by the day. For example, the degradation degree of the rock mass of the hydro-fluctuation belt at the bottom of the Wu Gorge Jianchuandong dangerous rock mass is deepened year by year, causing 55-mm accumulated displacement of the dangerous rock mass, and once collapse and instability occur, the secondary disaster of surge up to 45 m is expected to be caused. In addition, a plurality of potential collapsing and sliding masses formed due to rock mass degradation are found in Wu Gorge and Xiling Gorge, for example, Banbiyan dangerous rock masses, Guanmuling dangerous rock masses, Huangyanwo dangerous rock masses, etc., which severely threatens the Yangtze River channels and the life and property safety of people. Therefore, it is especially important to identify the potential landslide hazard site of the rock mass degradation area of the reservoir bank.

The potential landslide hazard of the degradation belt area of the reservoir is mainly identified through conventional field map sheet investigation or conventional engineering investigation currently, these methods mainly depend on the experience of professionals, and because of the limited coverage, a large amount of manpower resources are usually needed, wasting time and labor. As for identifying the landslide by the optical remote sensing interpretation technology, although the coverage area is larger and the landslide can be identified through man-machine interaction, the conventional optical remote sensing image is low in precision and misjudgment and missed judgment are prone to occur due to the steep hydro-fluctuation belt of the reservoir bank; and the technology is mostly used for positioning the existing landslide and cannot identify the potential landslide hazard sites, so many potential landslide hazard sites in the hydro-fluctuation belt area of the reservoir bank are difficult to effectively identify.

### SUMMARY

In view of this, the embodiment of the present disclosure provides a method for identifying a potential landslide hazard of a reservoir bank based on a rock mass degradation feature to solve the problems that the potential landslide hazard identification accuracy of a degradation belt of a reservoir is low, and misjudgment and missed judgment are likely to occur.

Embodiments of the present disclosure provide a method for identifying a potential landslide hazard of a reservoir bank based on a rock mass degradation feature, including:

S1, analyzing an aerial remote sensing data feature and field survey data, performing screening to determine a remote sensing interpretation identification mark of a potential landslide hazard site induced by rock mass degradation of a hydro-fluctuation belt of a bank slope, and establishing a potential landslide hazard site catastrophe evolution identification model according to the remote sensing interpretation identification mark;

S2, obtaining an orthoimage of a reservoir bank degradation belt in a survey area by oblique photography of an unmanned aerial vehicle, performing preliminary remote sensing interpretation on the orthoimage according to the remote sensing interpretation identification mark, and delineating an area prone to landslide;

S3, obtaining an oblique real-scene three-dimensional model of the area prone to landslide by the orthoimage, generating digital elevation model (DEM) data according to the oblique real-scene three-dimensional model for remote sensing fine interpretation, and identifying and extracting the remote sensing interpretation identification mark of the potential landslide hazard site; and

S4, inputting the remote sensing interpretation identification mark obtained in S3 into the potential landslide hazard site catastrophe evolution identification model to identify a catastrophe evolution mode of the potential landslide hazard site of the degradation belt.

Further, a specific method for performing preliminary remote sensing interpretation on the orthoimage includes: using pix4D software to group the orthoimages according to a sequence to generate one orthophoto map for each group, interpreting the orthophoto map for each group respectively, and delineating an area prone to landslide.

Further, a method for obtaining an oblique real-scene three-dimensional model in S3 includes:

using smart3D software to group the orthoimages of the area prone to landslide, performing aerial triangulation to generate point cloud data, and using an internal vector function relation algorithm of the smart3D software to form a triangular irregular network according to preset point cloud density, so as to construct a 3D model with points, lines and planes; and

matching depth images of different visual angles in the 3D model to a same coordinate, obtaining a complete 3D model of an object by depth image fusion, then determining a mapping relation between the summative depth image and a texture image of the 3D model, defining a composite weight for texture fusion to obtain a whole texture mapping image, carrying out texture mapping of the model, and finally constructing the oblique real-scene three-dimensional model.

Further, a specific method for generating DEM data according to the oblique real-scene three-dimensional model for remote sensing fine interpretation in S3 includes: obtaining the point cloud data of a rock mass degradation area by the oblique real-scene three-dimensional model to generate a high-precision DEM model, and using the DEM model to extract a bank slope gradient classification interval, so as to interpret the potential landslide hazard site to extract a remote sensing interpretation identification mark of the potential landslide hazard site.

Further, the remote sensing interpretation identification mark includes a degradation type, a structural plane development feature, a bank slope structure, lithology and rock mass structure, and a boundary feature.

Further, the degradation types include a corrosion subsurface erosion type, a crack manifesting and expansion type, a mechanical erosion type, a soft and hard alternate erosion type, a scouring abrasion type, a loose stripping type and a structural plane disintegration block-cracking type; the structural plane development features include large structural plane development and controlled structural plane development; the bank slope structures include a dip bank slope, an inclined dip bank slope, a bank slope in a counter direction and a gentle layered bank slope; in the lithology and rock mass structure, the lithology includes a carbonatite type rock mass and a clastic rock type rock mass, and the rock mass structure includes a blocky structure, a layered structure, a fragmentation structure, a loose structure and a soft and hard alternate structure; and the boundary feature is a boundary form of the potential landslide hazard site.

Further, the catastrophe evolution mode of the potential landslide hazard site of the degradation belt includes a base fragmentation crushing type, a base emptying toppling type, a forward sliding type, a soft and hard alternate crumbling type, an apparent tendency wedge-shaped sliding type and a reverse toppling type.

The technical solution provided in the embodiment of the present disclosure has the beneficial effects that the method for identifying a potential landslide hazard of a reservoir bank based on a rock mass degradation feature integrates a plane orthoimage, a three-dimensional multi-angle oblique image and high-precision digital elevation model (DEM) data, identification marks are determined according to development features of potential landslide hazard sites induced by rock mass degradation of different types, so as to establish a potential landslide hazard site catastrophe evolution identification model, which may early identify new landslide induced by rock mass degradation of the reservoir bank, a success rate of potential landslide hazard identification in a rock mass degradation area of the reservoir bank is greatly improved, the problem of poor orthoimage precision caused by a steep slope of the reservoir bank degradation belt in an existing interpretation method is effectively solved, and a probability of misjudgment and missed judgment is reduced.

### BRIEF DESCRIPTION OF THE DRAWINGS

FIG. 1 is a schematic diagram of a potential landslide hazard site catastrophe evolution identification model of a method for identifying a potential landslide hazard of a reservoir bank based on a rock mass degradation feature in the present disclosure;

FIG. 2 is a schematic diagram of a base fragmentation crushing type disaster of a hydro-fluctuation belt of a carbonatite type bank slope;

FIG. 3 is a schematic diagram of a base emptying toppling type disaster of the hydro-fluctuation belt of the carbonatite type bank slope;

FIG. 4 is a schematic diagram of a forward sliding type disaster of the hydro-fluctuation belt of the carbonatite type bank slope;

FIG. 5 is a schematic diagram of a soft and hard alternate crumbling (collapsing) type disaster of a hydro-fluctuation belt of a clastic rock type bank slope;

FIG. 6 is a schematic diagram of an apparent tendency wedge-shaped sliding type disaster of the hydro-fluctuation belt of the clastic rock type bank slope;

FIG. 7 is a schematic diagram of a forward sliding type disaster of the hydro-fluctuation belt of the clastic rock type bank slope;

FIG. 8 is a schematic diagram of a reverse toppling type disaster of the hydro-fluctuation belt of the clastic rock type bank slope;

FIG. 9 is an orthophoto map of a work area;

FIG. 10 is a digital elevation model (DEM) of the work area; and

FIG. 11 is an interpretation result of a potential landslide hazard site in a degradation belt of the reservoir bank of the work area.

### DETAILED DESCRIPTION OF THE EMBODIMENTS

In order to make the objective, technical solution and advantages of the present disclosure clearer, embodiments of the present disclosure will be further described in detail in conjunction with the accompanying drawings.

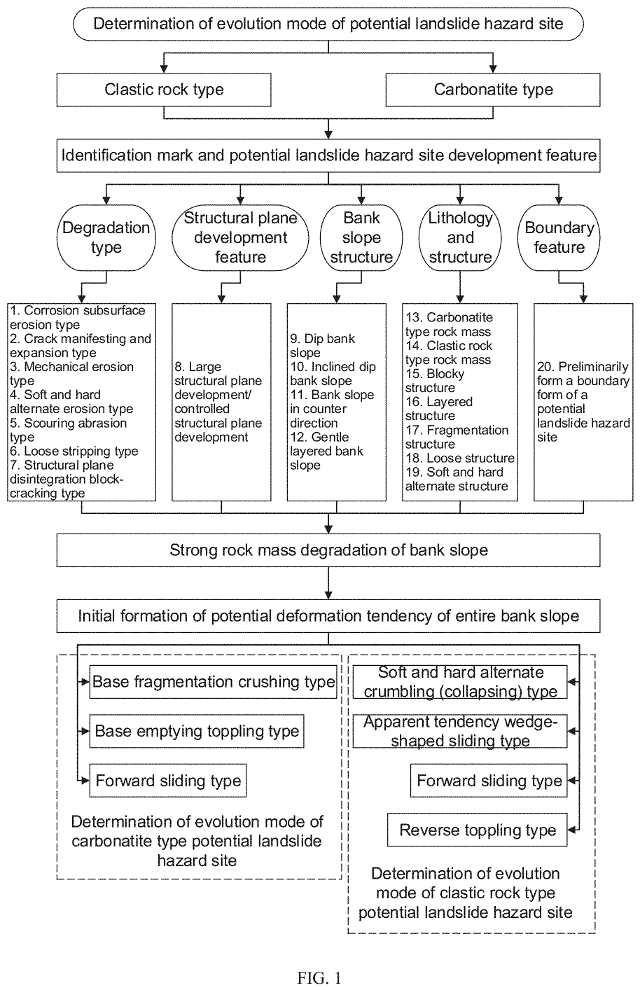

As shown in FIG. 1, the embodiment of the present disclosure provides a method for identifying a potential landslide hazard of a reservoir bank based on a rock mass degradation feature. The method includes:

S1, analyze an aerial remote sensing data feature and field survey data, perform screening to determine a remote sensing interpretation identification mark of a potential landslide hazard site induced by rock mass degradation of a hydro-fluctuation belt of a bank slope, and establish a potential landslide hazard site catastrophe evolution identification model according to the remote sensing interpretation identification mark

An analysis result of a rock mass degradation type of the hydro-fluctuation belt of the bank slope of a working area is mainly represented as two types of carbonatite type rock mass degradation and clastic rock type rock mass degradation according to the aerial remote sensing data feature and the field survey data, where the carbonatite type rock mass degradation is mainly divided into a corrosion/subsurface erosion type, a crack manifesting and expansion type and a mechanical erosion type; and the clastic rock type rock mass degradation is mainly divided into a loose/stripping type, an scouring/abrasion type, a structural plane disintegration block-cracking type and a soft and hard alternate erosion type.

It is summarized that the remote sensing interpretation identification mark for the potential landslide hazard site induced by the rock mass degradation of the hydro-fluctuation belt of the bank slope includes a degradation type, a structural plane development feature, a bank slope structure, lithology and rock mass structure, and a boundary feature.

The degradation types include a corrosion subsurface erosion type, a crack manifesting and expansion type, a mechanical erosion type, a soft and hard alternate erosion type, a scouring abrasion type, a loose stripping type and a structural plane disintegration block-cracking type; the structural plane development features include large structural plane development and controlled structural plane development; the bank slope structures include a dip bank slope, an inclined dip bank slope, a bank slope in a counter direction and a gentle layered bank slope; in the lithology and rock mass structure, the lithology includes a carbonatite type rock mass and a clastic rock type rock mass, and the rock mass structure include a blocky structure, a layered structure, a fragmentation structure, a loose structure and a soft and hard alternate structure; and the boundary feature is a boundary form of the potential landslide hazard site.

Meanwhile, a disaster evolution mode of the potential landslide hazard site is summarized, where the disaster evolution modes of the potential landslide hazard sites of the hydro-fluctuation belt of the carbonatite type bank slope include a base fragmentation crushing type, a base emptying toppling type and a forward sliding type; and the disaster evolution modes of the potential landslide hazard sites of the hydro-fluctuation belt of the clastic rock type bank slope include a soft and hard alternate crumbling (collapsing) type, an apparent tendency wedge-shaped sliding type, forward sliding type and reverse toppling type.

The remote sensing interpretation identification marks corresponding to the disaster evolution modes of various potential landslide hazard sites are described in detail.

(1) Evolution Mode of Potential Landslide Hazard Site of Carbonatite Type Rock Mass Degradation of Hydro-Fluctuation Belt of Bank Slope

1) Base Fragmentation Crushing Type

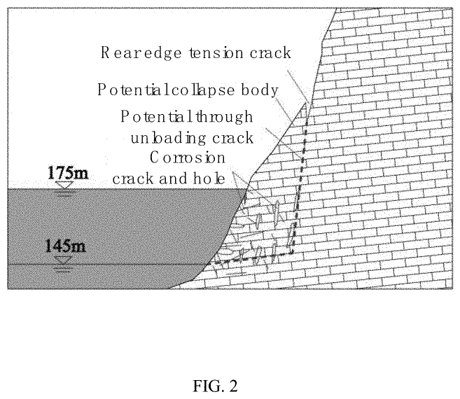

With reference to FIG. 2, when the rock mass of the bank slope is carbonatite rock, the rock mass is prone to karst geological effects, for example, corrosion and subsurface erosion, a base at the potential landslide hazard site is prone to corrosion and emptying, most of the base is located in a long-term dynamic water environment of the hydro-fluctuation belt of the bank slope and periodic fluctuation of a reservoir water level, a large number of grikes, water-eroded grooves, karst cracks and karst caves are developed on the base at the potential landslide hazard site, that is, the hydro-fluctuation belt of the bank slope, and when rainfall or other external forces exist, an upper rock mass gradually disintegrates along corrosion cracks, unloading cracks, etc., such that geological disasters of crumbling (collapsing) or landslide occur.

2) Base Emptying Toppling Type

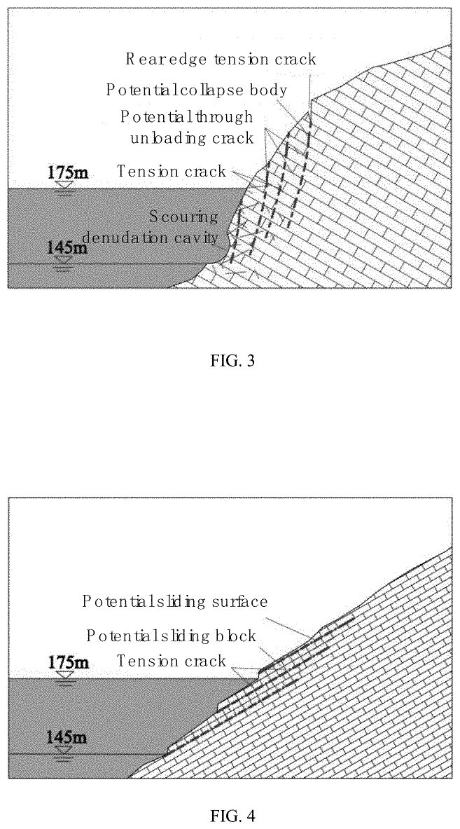

With reference to FIG. 3, a relatively weak rock mass at a reverse lower portion of the reservoir bank is continuously subjected to dry-wet circulation, softening, argillization and disintegration under the long-term action of reservoir water, such that a slope toe base is emptied, erosion cracks and erosion concave cavities with different shapes appear at the lower portion of the bank slope, an upper rock mass loses support, then toppling and crumbling (collapsing) disasters occur, and when the upper rock mass is unloaded and cracked, the hydro-fluctuation belt bank slope has local crumbling (collapse) damage with different scales.

3) Forward Sliding Type

With reference to FIG. 4, a large number of dip bank slopes develop in the hydro-fluctuation belt of the bank slope in the working area, scouring and rushing erosion occur under long-term fluctuation of the reservoir water level, corrosion effects such as corrosion and subsurface erosion may also occur on the carbonatite type bank slope, a forward layer is emptied all the year round, a large number of joint fissures along the layer and perpendicular to the layer gradually develop, a complete rock mass is cut by the new fissure perpendicular to the layer, and the rock mass cut by the fissures or the locally unstable rock mass slides to the reservoir area along the layer under the action of self gravity, wave erosion, etc. This mainly occurs in dip and oblique dip rock bank slope areas.

(2) Evolution Mode of Potential Landslide Hazard Site of Rock Mass Degradation of Hydro-Fluctuation Belt of Clastic Rock Type Bank Slope

1) Soft and Hard Alternate Crumbling (Collapsing) Type

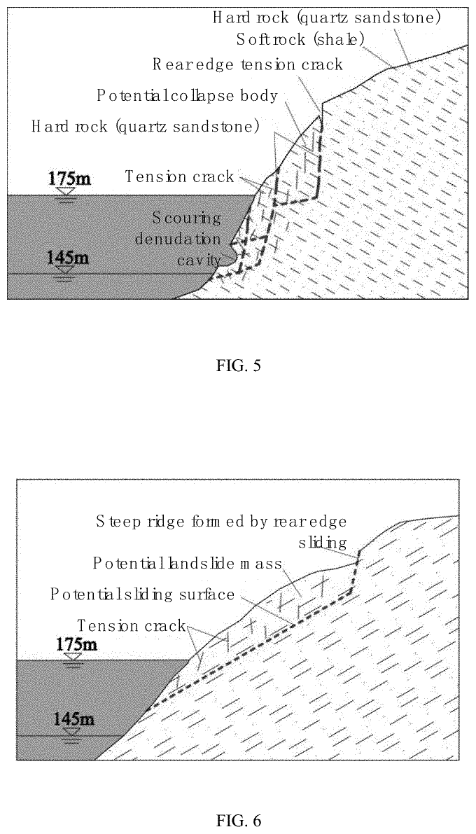

With reference to FIG. 5, a large number of soft and hard alternate rock hydro-fluctuation belts of the bank slope develop in the working area, soft rock (shale) in a slope body is softened and unloaded under long-term fluctuation of the reservoir water level, hard rock (sandstone) between layers is fractured and broken, a joint fissure develops gradually to form a through unloading crack perpendicular to the layer gradually, and after a local steep area is deformed and destroyed, the rock mass cut by the crack or the locally unstable rock mass crumbles (collapses) and slides towards the reservoir area. This mainly occurs in a steep area of a soft and hard alternate rock bank slope.

2) Apparent Tendency Wedge-Shaped Sliding Type

With reference to FIG. 6, under the long-term action of the reservoir water level, the rock mass (siltstone and mudstone) of the apparent tendency hydro-fluctuation belt of the bank slope is extremely prone to strong degradation under a water level variation condition and a periodic dry and wet alternating environment. After an anti-sliding body at a front edge of the slope body is subjected to rock mass degradation, two sliding surfaces (crossed wedge-shaped sliding surfaces) are gradually formed at a rear edge, and after a landslide mass gradually communicates at the wedge-shaped sliding surfaces, a bottom of the landslide mass is subjected to integral wedge-shaped sliding towards the reservoir area along a weak surface (belt), causing a landslide disaster, a scale is large, a sliding speed is high, and a certain sliding distance exists.

3) Forward Sliding Type

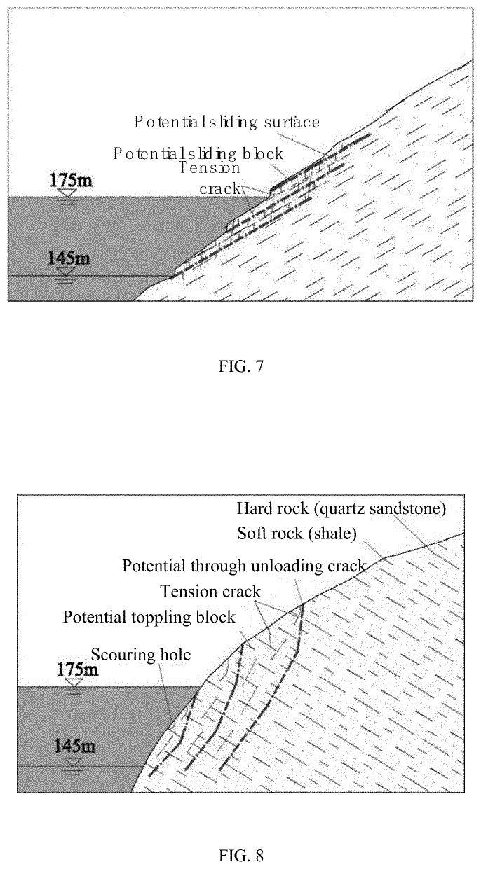

With reference to FIG. 7, the hydro-fluctuation belt of the dip bank slope continuously carries away fully-weathered and strongly-weathered rock-soil masses from a surface of the bank slope under the action of scouring, erosion and denudation of the reservoir water, and slowly backward scouring denudation damage occurs. Strength of an interlayer and a surface weak layer is reduced, such that the rock mass at the surface of the bank slope slides to the reservoir area along the layer, and the hydro-fluctuation belt of the bank slope forms an unstable slope. This is a typical evolution mode of a new clastic rock type landslide (hidden danger) in the working area. Firstly a local and a surface are damaged, and large-scale bedding slip of the upper rock mass may be caused after a “cut foot” is free.

4) Reverse Toppling Type

With reference to FIG. 8, under the action of long-term fluctuation of the reservoir water level and water flow, the rock mass of the hydro-fluctuation belt of the bank slope in a counter direction generates strong rock mass degradation to form a through unloading crack perpendicular to the layer gradually, and after the local steep area of the bank slope is deformed and destroyed along the unloading crack, the rock mass cut by the crack or the locally unstable rock mass crumbles (collapses) towards the reservoir area. This mainly occurs in a steep area of a clastic rock type bank slope.

Therefore, remote sensing interpretation identification marks corresponding to disaster evolution modes of various potential landslide hazard sites may be determined, and the remote sensing interpretation identification marks are determination conditions.

Three mode determining condition combinations for the evolution mode of the carbonatite type potential landslide hazard site are as follows:

(1) Base Fragmentation Crushing Type

Potential landslide hazard site combination conditions for forming the base fragmentation crushing type evolution mode include that rock mass degradation types are mainly a corrosion subsurface erosion type and a crack manifesting and expansion type, a large structural plane/controlled structural plane develops to form a boundary, the bank slope structures are mostly a bank slope in a counter direction or a gentle layered bank slope, the bank slope lithology is a carbonatite type rock mass, for example, hard carbonatite of limestone, dolomitic limestone and dolomite, the rock mass structure types are mostly a blocky structure or a layered structure or a fragmentation structure or a loose structure or a soft and hard alternate structure, a columnar shape is formed, and a boundary form of a potential dangerous rock mass is preliminarily formed.

(2) Base Emptying Toppling Type

Potential landslide hazard site combination conditions for forming the base emptying toppling type evolution mode include that rock mass degradation types are mainly a crack manifesting and expansion type and a mechanical erosion type, a large-scale outward-inclined or steep structural plane/controlled structural plane develops, the bank slope structures are mostly a bank slope in a counter direction or a gentle layered bank slope, the bank slope lithology is a carbonatite type rock mass, for example, hard carbonatite of limestone, dolomitic limestone and dolomite, the degraded rock mass structure types are mostly a fragmentation structure or a loose structure, overlying rock masses are mostly blocky or layered, and a boundary form of a potential dangerous rock mass is preliminarily formed.

(3) Forward Sliding Type

Potential landslide hazard site combination conditions for forming the forward sliding type evolution mode include that rock mass degradation types are mainly a corrosion subsurface erosion type, a crack manifesting and expansion type and a mechanical erosion type, the bank slope structures are mostly a dip bank slope or an inclined dip bank slope, the bank slope lithology is a carbonatite type rock mass, for example, limestone, dolomitic limestone, dolomite and other hard carbonatite, the rock mass structure types are mostly a blocky structure or a layered structure or a fragmentation structure, a layer develops or has a weak layer or a relatively weak layer sandwiched, and a boundary form of a potential landslide hazard site is preliminarily formed.

Four Mode Determining Condition Combinations for the Evolution Mode of the Clastic Rock Type Potential Landslide Hazard Site are as Follows:

Soft and Hard Alternate Crumbling (Collapsing) Type:

Rock mass degradation types mainly include a soft and hard alternate erosion type, a random structural plane develops, bank slope structures are mostly dip bank slopes or inclined dip bank slopes or bank slopes in a counter direction, bank slope lithology is a clastic rock type rock mass, for example, sand and mudstone interbedding, sandstone with shale, and other clastic rock, rock mass structures are mostly layered soft and hard alternate structures, and a boundary form of the potential landslide hazard site is preliminarily formed.

Apparent Tendency Wedge-Shaped Sliding Type:

Rock mass degradation types mainly include a scouring abrasion type and a structural plane disintegration block-cracking type, a large structural plane/controlled structural plane develops, bank slope structures are mostly dip bank slopes or inclined dip bank slopes, bank slope lithology is a clastic rock type rock mass, for example, sandstone, mudstone, shale, sand and mudstone interbedding, sandstone with shale, and other clastic rock, rock mass structures are mostly layered structures and sometimes have a weak layer or mudstone, and a boundary form of the potential landslide hazard site is preliminarily formed.

Forward Sliding Type:

Rock mass degradation types mainly include a scouring abrasion type and a structural plane disintegration block-cracking type, a large structural plane/controlled structural plane develops, bank slope structures are mostly dip bank slopes or inclined dip bank slopes, bank slope lithology is a clastic rock type rock mass, for example, sandstone, mudstone, shale, sand and mudstone interbedding, sandstone with shale, and other clastic rock, rock mass structures are mostly layered structures and have a weak layer, and a boundary form of the potential landslide hazard site is preliminarily formed.

Reverse Toppling Type:

Rock mass degradation types mainly include a soft and hard alternate erosion type, a loose stripping type, and a structural plane disintegration block-cracking type, a large and medium structural plane/controlled structural plane develops or a tracking large structural plane develops, bank slope structures are mostly bank slopes in a counter direction, bank slope lithology is a clastic rock type rock mass, for example, sandstone, mudstone, shale, sand and mudstone interbedding, sandstone with shale, and other clastic rock, rock mass structures are mostly layered structures or fragmented structures, and a boundary form of the potential landslide hazard site is preliminarily formed.

S2, obtain an orthoimage of a reservoir bank degradation belt in a survey area by oblique photography of an unmanned aerial vehicle, perform preliminary remote sensing interpretation on the orthoimage according to the remote sensing interpretation identification mark, and delineate an area prone to landslide

Since a synthetic image has extremely high pixels and an ordinary apparatus may not process massive original data to generate the orthoimages without the help of a special server, pix4D software is used to group the orthoimages according to a sequence to generate one orthophoto map for each group respectively, the orthophoto map for each group is interpreted respectively, and an area prone to landslide is delineated.

S3, obtain an oblique real-scene three-dimensional model of the area prone to landslide by the orthoimage, generate digital elevation model (DEM) data according to the oblique real-scene three-dimensional model for remote sensing fine interpretation, and identify and extract the remote sensing interpretation identification mark of the potential landslide hazard site Specifically,

smart3D software is used to group the orthoimages of the area prone to landslide, aerial triangulation is performed to generate point cloud data, and an internal vector function relation algorithm of the smart3D software is used to form a triangular irregular network according to preset point cloud density, so as to construct a 3D model with points, lines and planes; and

depth images of different visual angles in the 3D model are matched to a same coordinate, a complete 3D model of an object is obtained by depth image fusion, then a mapping relation between the summative depth image and a texture image of the 3D model is determined, a composite weight is defined for texture fusion to obtain a whole texture mapping image, texture mapping of the model is carried out, and finally the oblique real-scene three-dimensional model is constructed.

The point cloud data of a rock mass degradation area is obtained by the oblique real-scene three-dimensional model to generate a high-precision DEM model, and the DEM model is used to extract a bank slope gradient classification interval, so as to interpret the potential landslide hazard site to extract a remote sensing interpretation identification mark of the potential landslide hazard site.

S4, input the remote sensing interpretation identification mark obtained in S3 into the potential landslide hazard site catastrophe evolution identification model to identify a catastrophe evolution mode of the potential landslide hazard site of the degradation belt Since the remote sensing interpretation identification mark of the catastrophe evolution mode of the potential landslide hazard site of each type of degradation belt is determined, the catastrophe evolution mode of the potential landslide hazard site of the degradation belt may be determined directly according to the remote sensing interpretation identification mark, and the potential landslide hazard of the rock mass degradation area of the reservoir bank is identified in advance.

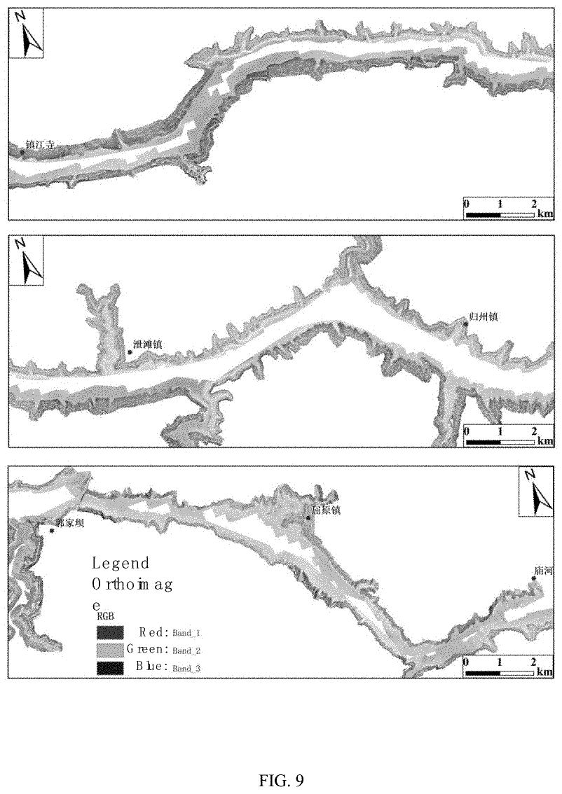

In order to further explain the advantages of high precision and small error of the method for identifying a potential landslide hazard of a reservoir bank based on a rock mass degradation feature, the embodiment also verifies the advantages of the method for identifying a potential landslide hazard of a reservoir bank based on a rock mass degradation feature. FIGS. 9, 10 and 11 show that the method for identifying a potential landslide hazard of a reservoir bank based on a rock mass degradation feature is used for determining a catastrophe evolution mode of a potential landslide hazard site of a hydro-fluctuation belt of a bank slope in a working area of Zhenjiang temple-Miaohe in the Three Gorges reservoir area.

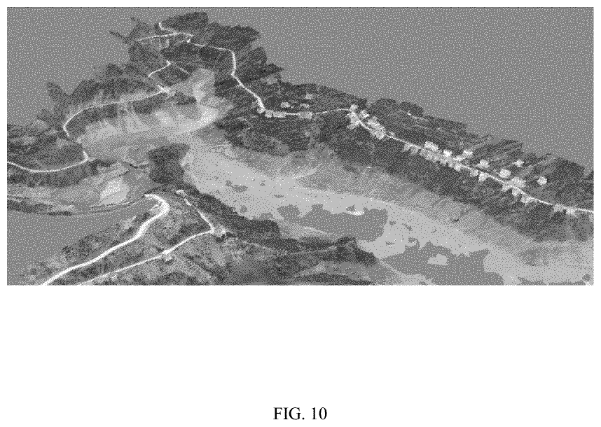

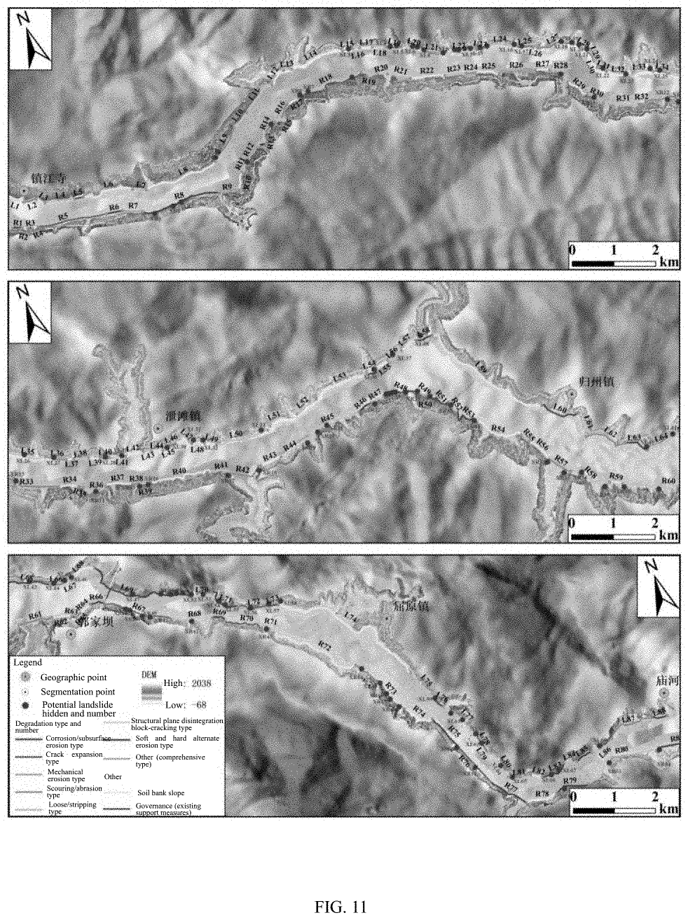

An orthoimage of the working area is shown in FIG. 9, a DEM of the working area is shown in FIG. 10, and an interpretation result of the potential landslide hazard site of the degradation belt of the reservoir bank of the working area is shown in FIG. 11. The embodiment identifies 116 potential hidden danger sites of the area prone to nascent landslide, where a left bank has 64 potential hidden danger sites and a right bank has 52 potential hidden danger sites. By field review, an accuracy rate is up to 90% or above.

Herein, the involved orientation terms such as “front”, “rear”, “upper”, and “lower” are defined in terms of the positions of parts and between the parts in the drawings, which are used just for clarity and convenience of expressing the technical solution. It should be understood that the use of such orientation terms should not limit the protection scope claimed by the present disclosure.

The above embodiments and the features of the embodiments herein may be combined with each other without conflict.

The above description is merely preferred embodiments of the present disclosure but not intended to limit the present disclosure, and any modifications, equivalent replacements, improvements, etc. made within the spirit and principles of the present disclosure should be included within the scope of protection of the present disclosure.

What is claimed is:

1. A method for identifying a potential landslide hazard of a reservoir bank based on a rock mass degradation feature, comprising:
S1, analyzing an aerial remote sensing data feature and field survey data, performing screening to determine a remote sensing interpretation identification mark of a potential landslide hazard site induced by rock mass degradation of a hydro-fluctuation belt of a bank slope, and establishing a potential landslide hazard site catastrophe evolution identification model according to the remote sensing interpretation identification mark;
S2, obtaining an orthoimage of a reservoir bank degradation belt in a survey area by oblique photography of an unmanned aerial vehicle, performing preliminary remote sensing interpretation on the orthoimage according to the remote sensing interpretation identification mark, and delineating an area prone to landslide;
S3, obtaining an oblique real-scene three-dimensional model of the area prone to landslide by the orthoimage, generating digital elevation model (DEM) data according to the oblique real-scene three-dimensional model for remote sensing fine interpretation, and identifying and extracting the remote sensing interpretation identification mark of the potential landslide hazard site; and
S4, inputting the remote sensing interpretation identification mark obtained in S3 into the potential landslide hazard site catastrophe evolution identification model to identify a catastrophe evolution mode of the potential landslide hazard site of the degradation belt.

2. The method according to claim 1, wherein the performing preliminary remote sensing interpretation on the orthoimage comprises: using pix4D software to group orthoimages according to a sequence to generate one orthophoto map for each group respectively, interpreting the orthophoto map for each group respectively, and delineating the area prone to landslide.

3. The method according to claim 1, wherein the obtaining an oblique real-scene three-dimensional model in S3 comprises:
using smart3D software to group orthoimages of the area prone to landslide, performing aerial triangulation to generate point cloud data, and using an internal vector function relation algorithm of the smart3D software to form a triangular irregular network according to preset point cloud density, so as to construct a 3D model with points, lines and planes; and
matching depth images of different visual angles in the 3D model to a same coordinate, obtaining a complete 3D model of an object by depth image fusion, then determining a mapping relation between a summative depth image and a texture image of the 3D model, defining a composite weight for texture fusion to obtain a whole texture mapping image, carrying out texture mapping of the 3D model, and finally constructing the oblique real-scene three-dimensional model.

4. The method according to claim 3, wherein the generating DEM data according to the oblique real-scene three-dimensional model for remote sensing fine interpretation in S3 comprises: obtaining the point cloud data of a rock mass degradation area by the oblique real-scene three-dimensional model to generate a high-precision DEM model, and using the DEM model to extract a bank slope gradient classification interval, so as to interpret the potential landslide hazard site to extract the remote sensing interpretation identification mark of the potential landslide hazard site.

5. The method according to claim 1, wherein the remote sensing interpretation identification mark comprises a degradation type, a structural plane development feature, a bank slope structure, lithology and rock mass structure, and a boundary feature.

6. The method according to claim 5, wherein the degradation types comprise a corrosion subsurface erosion type, a crack manifesting and expansion type, a mechanical erosion type, a soft and hard alternate erosion type, a scouring abrasion type, a loose stripping type and a structural plane disintegration block-cracking type; the structural plane development features comprise large structural plane development and controlled structural plane development; the bank slope structures comprise a dip bank slope, an inclined dip bank slope, a bank slope in a counter direction and a gentle layered bank slope; in the lithology and rock mass structure, the lithology comprises a carbonatite type rock mass and a clastic rock type rock mass, and the rock mass structure comprise a blocky structure, a layered structure, a fragmentation structure, a loose structure and a soft and hard alternate structure; and the boundary feature is a boundary form of the potential landslide hazard site.

7. The method according to claim 1, wherein the catastrophe evolution mode of the potential landslide hazard site of the degradation belt comprises a base fragmentation crushing type, a base emptying toppling type, a forward sliding type, a soft and hard alternate crumbling type, an apparent tendency wedge-shaped sliding type and a reverse toppling type.
